(19) United States
(12) Patent Application Publication
(10) Pub. No.: US 2026/0221182 A1
(43) Pub. Date: Jul. 30, 2026

(54) SEMICONDUCTOR MEMORY DEVICE

(71) Applicant: SK hynix Inc., Gyeonggi-do (KR)

(72) Inventors: Jae Gil LEE, Gyeonggi-do (KR); Won Tae KOO, Gyeonggi-do (KR)

(21) Appl. No.: 19/182,598

(22) Filed: Apr. 18, 2025

(30) Foreign Application Priority Data
Jan. 24, 2025 (KR) 10-2025-0011319

(51) Int. Cl. G11C 11/4096; G11C 5/06

(52) U.S. Cl. CPC G11C 11/4096; G11C 5/063

(57) ABSTRACT

A semiconductor memory device may include a write transistor, a read transistor, and a one-way switch. The write transistor may be configured to output a signal of a write bit line as data in response to a signal of a write word line. The read transistor may be configured to store the data and to output the stored data to a read bit line in response to a signal of a read word line. The one-way switch may be configured to transmit the data in one direction from the write transistor to the read transistor.

### CROSS-REFERENCES TO RELATED APPLICATION

The present application claims priority under 35 U.S.C. §119(a) to Korean application number 10-2025-0011319, filed on Jan. 24, 2025, which is incorporated herein by reference in its entirety.

### BACKGROUND

### 1. Technical Field

Embodiments of the present disclosure relate generally to an electronic device, and more particularly, to a semiconductor memory device including a memory cell.

### 2. Related Art

A DRAM device, which may be representative of a semiconductor memory device, may include a plurality of unit memory cells including typically one transistor and one capacitor. Currently, to improve performance of the DRAM device, methods of integrating a larger number of unit memory cells in a limited area and methods of fabricating capacitors with a larger capacity within a limited area are being researched.

Recently, to reduce an occupied area of the memory cell, there has been extensive research on memory cell structures configured to enable higher cell densities by reducing a size of a capacitor or omitting a capacitor in order to reduce the occupied area of the memory cell.

### SUMMARY

Embodiments of the present disclosure in their broadest aspects relate to a semiconductor memory device including a memory cell without a capacitor (hereinafter “capacitorless memory cell”). The memory cell comprises a write transistor and a read transistor.

Embodiments of the present disclosure provide a semiconductor memory device including a capacitorless memory cell that is capable of preventing data loss.

According to various embodiments, there is provided a semiconductor memory device comprising a write transistor, a read transistor and a one-way switch. The write transistor may output a signal of a write bit line as data in response to a signal of a write word line. The read transistor may store the data. The read transistor may output the stored data to a read bit line in response to a signal of the read word line. The one-way switch may transmit the data from the write transistor to the read transistor in one direction.

According to embodiments of the present disclosure, there is provided a semiconductor memory device comprising a write bit line, a write transistor, a one-way switch and a read transistor. The write transistor may be stacked over the write bit line in electrical connection with the write bit line. The one-way switch may be stacked over the write transistor. The read transistor may be stacked over the one-way switch.

In some embodiments, the write transistor may include a first channel pillar, a first gate insulation layer, a first gate, a first source and a first drain. The first channel pillar may extend in a direction perpendicular to a surface of the write bit line. The first channel pillar may include a semiconductor material. The first gate insulation layer may be formed to surround an outer circumferential surface of the first channel pillar. The first gate may be formed to surround an outer circumferential surface of the first gate insulation layer. The first gate may be electrically connected to the write bit line. The first source may be formed in a lower region of the first channel pillar. The first source may be electrically connected to the write bit line. The first drain may be formed in an upper region of the first channel pillar. The first drain may be electrically connected to the one-way switch.

In some embodiments, the one-way switch may include a first drain contact electrode and an n-type semiconductor layer. The first drain contact electrode may be formed on the first drain. The first drain contact electrode may include a metal. The n-type semiconductor layer may be formed on the first drain contact electrode.

In some embodiments, the one-way switch may include a p-type semiconductor layer and an n-type semiconductor layer. The p-type semiconductor layer may be formed on the first drain. The p-type semiconductor layer may be electrically connected to the first drain. The n-type semiconductor layer may be formed on the p-type semiconductor layer in contact with the p-type semiconductor layer.

In some embodiments, the read transistor may include a second gate, a second gate insulation layer, a second channel layer, a second source and a second drain. The second gate may be stacked over the one-way switch. The second gate may be connected electrically with the one-way switch. The second gate insulation layer may be formed on the second gate. The second channel layer may be formed on the second gate insulation layer. The second source may be located at one side of the second channel layer. The second source may be electrically connected to the read word line. The second drain may be located on the other side of the second channel layer. The second drain may be electrically connected to the read bit line.

According to embodiments of the present disclosure, there is provided a semiconductor memory device comprising a write transistor, a forward diode and a read transistor. The write transistor may include a first source in connection with a write bit line, a vertical channel layer formed on the first source, a first drain formed on the vertical channel, a first gate insulation layer configured to surround outer circumferential surfaces of the first source, the vertical channel layer and the first drain, and a first gate configured to surround an outer circumferential surface of the first gate insulation layer. The forward diode may be stacked over the first drain of the write transistor. The read transistor may include a second gate stacked over the forward diode, a second gate insulation layer formed on the second gate, a horizontal channel layer positioned on the second gate insulation layer, a second source positioned on one side of the horizontal channel layer, and a second drain positioned on the other side of the horizontal channel layer.

According to some embodiments, the one-way switch may be formed between the write transistor and the read transistor. The one-way switch may prevent data stored in the read transistor from flowing into the write bit line connected to the write transistor in an unselected mode. Accordingly, a data retention rate of the capacitorless memory cell may be improved.

### BRIEF DESCRIPTION OF THE DRAWINGS

The above and other aspects, features and advantages of the embodiments of the present disclosure will be more easily understood from the following detailed description taken in conjunction with the accompanying drawings, in which:

FIG. 1 is a circuit diagram illustrating a capacitorless memory cell of a semiconductor memory device in accordance with an embodiment of the present disclosure;

FIG. 2 is a circuit diagram illustrating a semiconductor memory device including capacitorless memory cells;

FIG. 3 is a circuit diagram illustrating a semiconductor memory device including capacitorless memory cells in accordance with an embodiment of the present disclosure;

FIGS. 4A and 4B are plan views illustrating a memory cell in two dimensions in accordance with an embodiment of the present disclosure;

FIGS. 5A and 5B are cross-sectional views taken along a line A-A′ of FIG. 4A; and

FIGS. 6A and 6B are cross-sectional views illustrating a three-dimensional capacitorless memory cell in accordance with an embodiment of the present disclosure.

### DETAILED DESCRIPTION

The advantages and features of the embodiments of the present disclosure, and methods of achieving them, will become apparent upon reference to the embodiments described in detail with reference to the accompanying drawings. However, the embodiments are not limited to the embodiments disclosed herein, but may be embodied in many variations or different forms, and these embodiments are provided merely to make this disclosure complete and to give a complete picture of the scope of the present disclosure to one of ordinary skill in the art. The dimensions and relative sizes of the layers and regions in the drawings may be exaggerated for clarity of description. Throughout this specification, like reference numerals refer to like components.

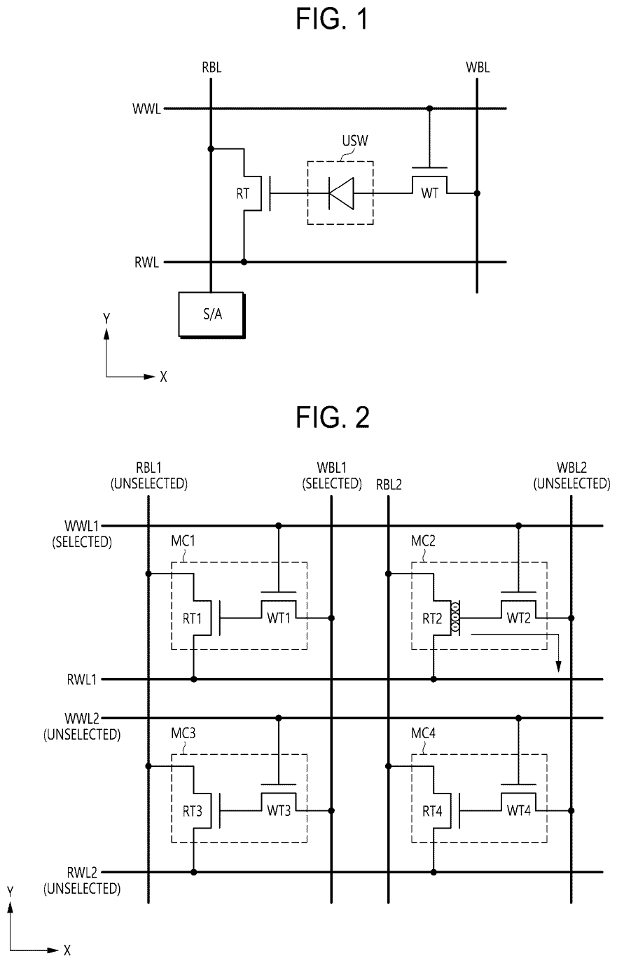

FIG. 1 is a circuit diagram illustrating a capacitorless memory cell of a semiconductor memory device in accordance with an embodiment of the present disclosure.

Referring to FIG. 1, a semiconductor memory device 10 may include a write word line WWL, a read word line RWL, a write bit line WBL, a read bit line RBL, and a memory cell MC electrically connected therebetween.

The memory cell MC may include a write transistor WT, a read transistor RT and a one-way switch USW.

In some embodiments, the write word line WWL and the read word line RWL may extend parallel along a first direction “X”. The write bit line WBL and the read bit line RBL may extend parallel along a second direction “Y” perpendicular to the first direction “X”.

The write transistor WT may be connected between the write word line WWL and the write bit line WBL. When the write word line WWL is enabled, the write transistor WT may output a voltage of the write bit line WBL as write data. For example, a gate of the write transistor WT may be connected to the write word line WWL. A source of the write transistor WT may be connected to the write bit line WBL. A drain of the write transistor WT may output the write data. The write data flows from the write bit line WBL, through the write transistor WT, and is transferred via the drain of the write transistor to the read transistor RT.

The read transistor RT may be connected between the read word line RWL and the read bit line RBL. In response to the write data outputted from the write transistor WT, the read transistor RT may transmit a voltage of the read word line RWL to the read bit line RBL. For example, a gate of the read transistor RT may be connected with the one-way switch USW. A source of the read transistor RT may be connected with the read word line RWL. A drain of the read transistor RT may be connected with the read bit line RBL.

The one-way switch USW may be connected between the write transistor WT and the read transistor RT. The one-way switch USW may be turned on when the output voltage of the write transistor WT is greater than a threshold voltage, i.e., an input voltage of the read transistor RT. For example, when the memory cell MC is in a non-selected state, it may prevent a current from flowing from the gate of the read transistor RT to the source of the write transistor WT, even if a write enable voltage is applied to the gate of the write transistor WT. The one-way switch USW may be a forward diode and may be connected between the drain of the write transistor WT and the gate of the read transistor RT. In some embodiments, the forward diode may be at least one of a rectifier diode, a Schottky barrier diode and a PN diode.

When the write enable voltage is applied to the gate of the write transistor WT via the write word line WWL and the write voltage is applied to the source of the write transistor WT via the write bit line WBL, the write transistor WT may be turned on. Accordingly, the drain of the write transistor WT may have the write voltage level.

When a drain voltage level of the write transistor is greater than a gate voltage level of the read transistor RT by the threshold voltage, the one-way switch USW may be turned on. The one-way switch USW may activate when the drain voltage of the write transistor WT exceeds the gate voltage of the read transistor RT by the threshold voltage. Accordingly, the drain voltage of the write transistor WT may be transmitted to the gate of the read transistor RT, thereby charging a gate insulation layer (not shown) of the read transistor RT. For example, the gate insulation layer of the read transistor RT may be operated as a charge storage layer of a memory cell. This means that the gate insulation layer may hold electrical charges, which may represent stored data in the memory cell.

On the other hand, when the gate insulation layer of the read transistor RT is charged and the read voltage is transmitted to the source of the read transistor RT via the read word line RWL, the read voltage may then be transmitted to the read bit line RBL based on an amount of the charge in the gate insulation layer.

A sense amplifier S/A may be connected to each of the read bit lines RBL. The sense amplifier S/A may sense a voltage of the read bit line RBL according to the data stored in the memory cell MC.

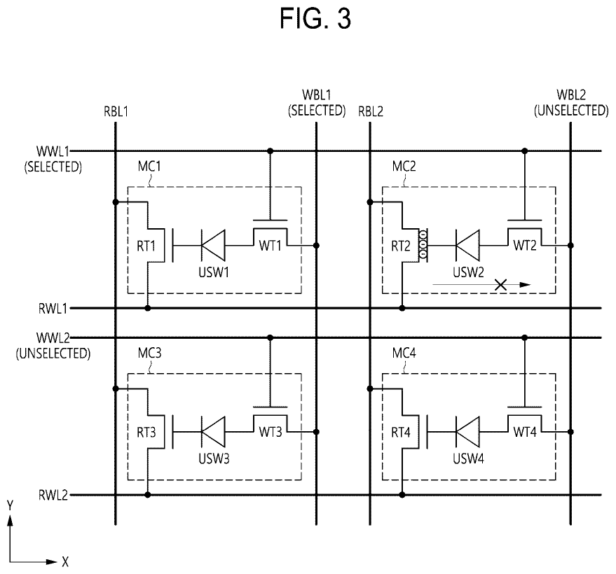

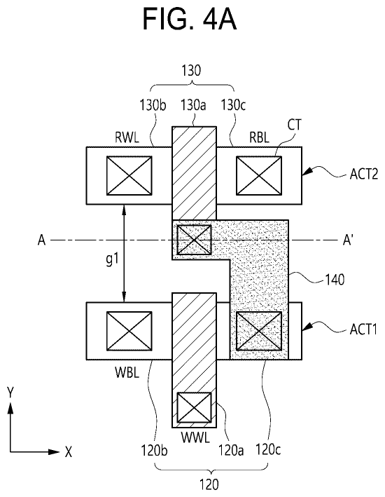

FIG. 2 is a circuit diagram illustrating a semiconductor memory device including typical capacitorless memory cells. FIG. 3 is a circuit diagram illustrating a semiconductor memory device including capacitorless memory cells in accordance with an embodiment of the present disclosure.

As shown in FIG. 2, first to fourth memory cells MC1-MC4 arranged in a matrix form may be connected between first and second write word lines WWL1 and WWL2, first and second write bit lines WBL1, WBL2, first and second read word lines RWL1, RWL2, and first and second read bit lines RBL1, RBL2. Each of the first to fourth memory cells MC1-MC4 may include a write transistor WT and a read transistor RT, without a one-way switch.

For example, when a write enable voltage may be applied to the first write word line WWL1 and a write voltage may be applied to the first write bit line WBL1, a data write operation may be performed on the first memory cell MC1. For reference, in FIG. 2, the first write word line WWL1 to which the write enable voltage may be applied may be labeled as selected, and the second write word line WWL2 to which the write enable voltage may not be applied may be labeled as unselected. Similarly, the first write bit line WBL1 to which the write voltage may be applied may be marked as selected, and the second write bit line WBL2 to which the write voltage may not be applied may be marked as unselected.

For example, prior to a write operation of the first memory cell MC1, “high” data may be pre-stored in the second memory cell MC2.

The write transistor WT2 of the second memory cell MC2 may be turned on by the selected first write word line WWL1, even though it is a non-selected memory cell. As a result, charges stored in the read transistor RT2 may flow into the non-selected second bit line WBL2 to cause the data in the second memory cell MC2 to be lost.

However, as shown in FIG. 3, the one-way switches USW1-USW4 which have a forward diode, are connected between the write transistors WT1-WT4 and the read transistors RT1-RT4 of the first to fourth memory cells MC4. Even if, “high” data are stored in the unselected second memory cell MC2 which is connected to the selected first write word line WWL1, the charges stored in the read transistor RT2 may be prevented by the one-way switch USW2 from flowing back to the second write bit line WBL2, thereby preserving the data.

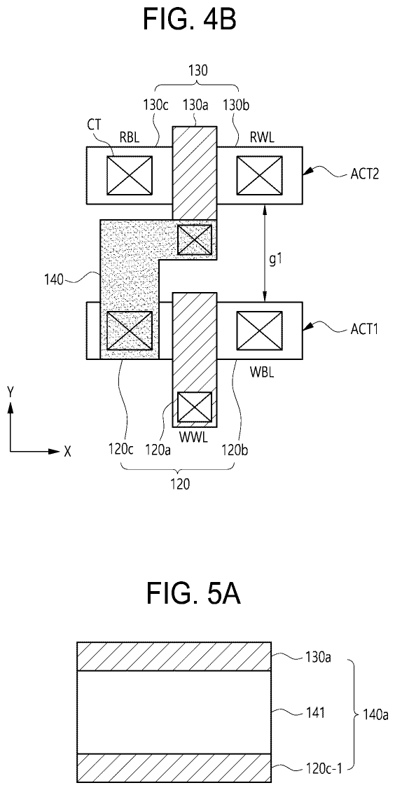

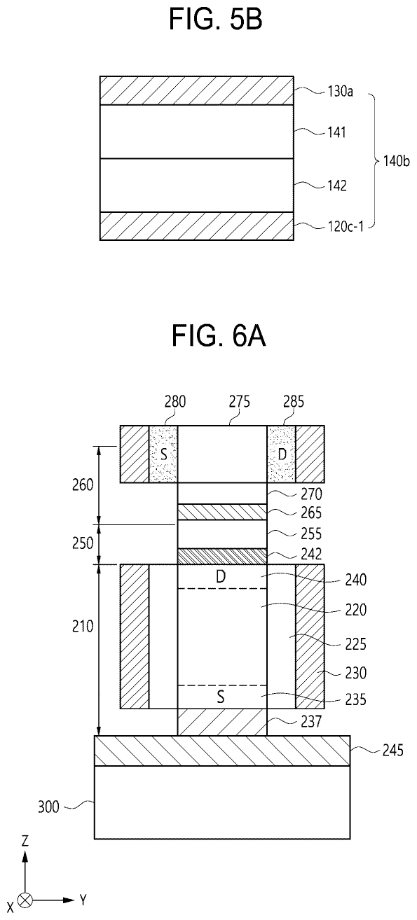

FIGS. 4A and 4B are plan views illustrating a memory cell in two dimensions in accordance with an embodiment of the present disclosure, and FIGS. 5A and 5B are cross-sectional views taken along line A-A′ of FIG. 4A.

Referring to FIG. 4A, an isolation layer 110 may be formed in a semiconductor substrate (not shown) to define a first active region ACT1 and a second active region ACT2. The semiconductor substrate may include, for example, silicon, germanium, gallium arsenide, molybdenum selenide (MoSe2), hafnium selenide (HfSe2), indium selenide (InSe), gallium selenide (GaSe), black phosphorus, indium-gallium-zinc oxide (IGZO), or combinations thereof. The substrate 101 may be doped with n-type or p-type dopants.

In some embodiments, the first active region ACT1 may be a region where a write transistor may be integrated. The second active region ACT2 may be a region where a read transistor may be formed. The first and second active regions ACT1 and ACT2 may have the same size. Alternatively, the first and second active regions ACT1 and ACT2 may have different sizes. The first and second active regions ACT1 and ACT2 may be spaced apart by a set gap g1. The first and second active regions ACT1 and ACT2 may be disposed two-dimensionally on the semiconductor substrate 101. Further, the first and second active regions ACT1 and ACT2 may extend parallel along an X-axis direction of FIGS. 4A and 4B, i.e., channels of the write transistor and the read transistor may extend horizontally in the X-axis direction.

A first gate 120a may be disposed over the first active region ACT1. A second gate 130a may be disposed over the second active region ACT2. For example, the first gate 120a and the second gate 130a may extend along a Y-axis direction of FIGS. 4A and 4B. The first gate 120a and the second gate 130a may be electrically isolated from each other.

In some embodiments, a first source 120b may be formed in the first active region ACT1 on one side of the first gate 120a. A first drain 120c may be formed in the first active region ACT1 on the other side of the first gate 120a. The first source 120b and the first drain 120c may include, for example, n-type conductive impurities. Accordingly, the write transistor 120 may be integrated in the first active region ACT1.

A second source 130b may be disposed in a second active region ACT2 on one side of the second gate 130a. A second drain 130c may be disposed in the second active region ACT2 on the other side of the second gate 130a. The second source 130b and the second drain 130c may also include n-type conductive impurities. Accordingly, the write transistor 130 may be integrated in the second active region ACT2.

In some embodiments, the first gate 120a may be in contact with the write word line WWL. The first source 120b may be in contact with the write bit line WBL.

The second source 130b may be in contact with the read word line RWL. The second drain 130c may be in contact with the read bit line RBL. In FIGS. 4A and 4B, a reference numeral CT may indicate a contact portion.

Further, although not shown in FIG. 4A, a second source electrode, a second drain electrode, a first source electrode and a first drain electrode including a metal may be formed on the first source 120b, the first drain 120c, the second source 130a, and the second drain 130b, respectively. For example, the second source electrode, the second drain electrode, the first source electrode and the first drain electrode may be operated as an ohmic contact layer.

Further, the one-way switch 140 may have a form of a wiring structure which is electrically connected between the first gate 120a and the second drain 130c. The one-way switch 140 may be positioned in the set gap G1.

Further, as shown in FIG. 4B, the first source 120b which is electrically connected to the write bit line WBL may be formed in the first active region ACT1 on the other side of the first gate 120a. The first drain 120c, which is electrically connected to the second gate 130a, may be formed in the first active region ACT1 on one side of the first gate 120a. Similarly, the second source 130b which is electrically connected to the read word line RWL, may be formed in the second active region ACT2 on the other side of the second gate 130a. The second drain 130c which is electrically connected to the read bit line RBL may be formed in the second active region ACT2 on one side of the second gate 130a.

However, it is noted that the embodiments may not be limited to the described layout structures, and in some embodiments the layout structures of the write and read transistors may be changed without departing from the scope of the present disclosure.

In some embodiments, as shown in FIG. 5A, a one-way switch 140a may include an n-type semiconductor layer 141. The n-type semiconductor layer 141 may be a polysilicon layer including n-type conductive impurities. The n-type semiconductor layer 141 may connect between the second gate 130a including a metal and a first drain electrode 120c-1 to form a wiring structure in a form of a Schottky barrier diode. Accordingly, when the memory cell is not selected, data stored in the read transistor 130 may be prevented from flowing into the write bit line WBL by the one-way switch 140a.

In another embodiment, as shown in FIG. 5B, a one-way switch 140b may be a wiring structure including an n-type semiconductor layer 141 and a p-type semiconductor layer 142 stacked on each other. For example, the n-type semiconductor layer 141 may be in contact with the second gate 130a, while the p-type semiconductor layer 142 may form a p-n junction with the n-type semiconductor layer 141 and may contact a first drain contact electrode 120c-1 on a surface of the first drain 120c. Accordingly, the one-way switch 140B may be operated as a PN diode, thereby preventing loss of data stored in the read transistor.

Each of the read transistor 120 and the write transistor 130 in accordance with various embodiments may have a horizontal channel in a two-dimensional shape. The one-way switch 140 may be configured in the form of wiring connected between the second gate 120a of the read transistor 120 and the first drain contact electrode 120c-1 of the write transistor 130.

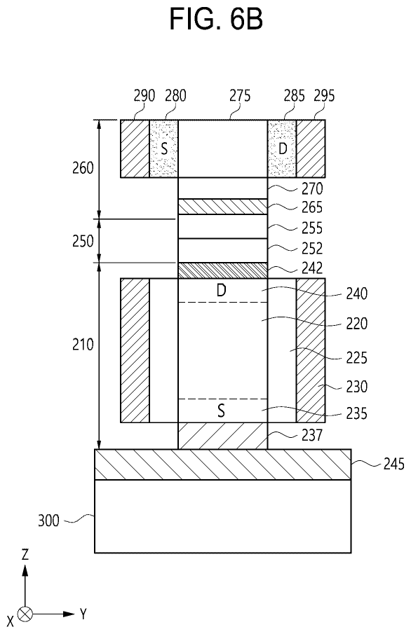

FIGS. 6A and 6B are cross-sectional views illustrating a three-dimensional capacitorless memory cell in accordance with an embodiment of the present disclosure.

Referring to FIG. 6A, a capacitorless memory cell 20 may include a write transistor 210 having a vertical channel, a one-way switch 250 and a read transistor 280 having a flat channel.

The write transistor 210 may include a first channel pillar 220, a first gate insulation layer 225, a first gate 230, a first source 235 and a first drain 240.

The first channel pillar 220 may extend toward a z-direction of FIG. 6A. The first channel pillar 220 may include a semiconductor material, e.g., a semiconductor, a conductive metal oxide, a transition metal chalcogenide, or a combination of two or more thereof. In some embodiments, the semiconductor may include doped silicon. In some embodiments, the conductive metal oxide may include indium oxide (In₂O₃), dopant-doped indium oxide (In₂O₃), indium gallium zinc oxide (InGaZnO₄), zinc oxide (ZnO), indium gallium oxide (InGaO₃), and the like. The dopant may include titanium (Ti), tungsten (W), silicon (Si), or any combination of two or more thereof. For example, the first channel pillar 220 may be a region where the channel of the write transistor may be formed and may include a first conductive type, e.g., p-type impurity.

The first gate insulation layer 225 may be formed to surround a sidewall of the first channel pillar 220. For example, the first gate insulation layer 225 may be formed to surround an entire outer wall of the first channel pillar 220 and may contact the outer wall of the first channel pillar 220. For example, the first gate insulation layer 225 may include a silicon oxide, a silicon nitride, a silicon oxynitride, an aluminum oxide, a hafnium oxide, a zirconium oxide, or two or more combinations thereof.

The first gate 230 may be formed to surround an outer wall of the first gate insulation layer 225, i.e., the first gate 230 may have a surround gate structure and may be electrically connected to a write word line (not shown) extending in the x-axis direction. The first gate 230 may contact the outer wall of the first gate insulation layer 225. The first gate 230 may include a conductive layer, for example, a polysilicon layer or metal layer comprising conductive impurities. The first gate 230 and the write word line may include, for example, the same conductive material, but the embodiments are not limited thereto. For example, the first gate 230 and the write word line may include a doped semiconductor, metal, conductive metal nitride, conductive metal carbide, conductive metal silicide, conductive metal oxide, or two or more combinations thereof.

The first source 235 may be a conductive impurity region located in a lower region of the first channel pillar 220. The first drain 240 may be a conductive impurity region located in an upper region of the first channel pillar 220. The first source 235 and the first drain 240 may include a second conductive impurity opposite to the first conductive impurity, for example, a high concentration of n-type impurity. In some embodiments, the first source 235 and the first drain 240 may be formed by an impurity ion implantation process.

A first source electrode 237 may be formed on a surface of the first source 235. A first drain electrode 242 may be formed on a surface of the first drain 240. For example, the first source electrode 237 and the first drain electrode 242 may each be an ohmic contact layer to reduce contact resistance. For example, the ohmic contact layer may comprise a metal silicide material.

A write bit line 245 may be formed under the write transistor 210 to contact the first source electrode 237. For example, as illustrated in FIG. 6A, the write bit line 245 may be positioned below the first source electrode 237 and may contact the first source electrode 237. For example, the write bit line 245 may include a metal. The write bit line 245 may extend along the Y-direction. The write bit line 245 may be formed prior to forming the write transistor 210, or in some cases, may be formed after forming the write transistor 210.

The one-way switch 250 may be stacked over the write transistor 210. The one-way switch 250 may include an n-type semiconductor material layer 255 in contact with the first drain electrode 242, as shown in FIG. 6A. The n-type semiconductor material layer 255 may be operated as a cathode, and the first drain electrode 242 may be operated as an anode, to form a forward Schottky barrier diode. The forward Schottky barrier diode may be operated as the one-way switch 250.

Further, the one-way switch 250 may include a stacked structure of a p-type semiconductor material layer 252 and an n-type semiconductor material layer 255, as shown in FIG. 6B. The p-type semiconductor material layer 252, which is an anode, may be electrically contacted with the first drain electrode 242. The n-type semiconductor material layer 255, which is a cathode, may be electrically connected with the read transistor 260, and in particular, a second gate 265 of the read transistor thereby configuring the one-way switch 250 as a forward PN diode.

The read transistor 260 may be stacked over the one-way switch 250. For example, the read transistor 260 may include the second gate 265, a second gate insulation layer 270 over the second gate 265, a horizontal channel layer 275 over the second gate insulation layer 270, a second source 280 and a second drain 285.

The second gate 265 may be electrically connected to an upper surface of the one-way switch 250. The second gate 265 may include a conductive material. For example, the conductive material may include at least one of a conductive metal nitride, a conductive metal carbide, a conductive metal silicide, and a conductive metal oxide. The conductive material may include, for example, n-type doped silicon, platinum, gold, palladium, molybdenum, nickel, tungsten, titanium, copper, aluminum, ruthenium, iridium, iridium oxide, tungsten nitride, titanium nitride, tantalum nitride, tungsten carbide, titanium carbide, tungsten silicide, titanium silicide, tantalum silicide, ruthenium oxide, or two or more combinations thereof.

The horizontal channel layer 275 may be disposed over the second gate 265. For example, the horizontal channel layer 275 may have a semiconductor material. In some embodiments, the horizontal channel layer 275 may include a semiconductor, a conductive metal oxide, a transition metal dichalcogenide, or a combination of two or more thereof. In some embodiments, the semiconductor may include doped silicon. In another embodiment, the conductive metal oxide may include indium oxide (In₂O₃), dopant-doped indium oxide (In₂O₃), indium gallium zinc oxide (InGaZnO₄), zinc oxide (ZnO), indium gallium oxide (InGaO₃), and the like. The dopant may include titanium (Ti), tungsten (W), silicon (Si), or any combination of two or more thereof. For example, the semiconductor material layer may include a first conductive impurity.

The second gate insulation layer 270 may be interposed between the second gate 265 and the horizontal channel layer 275. The second gate insulation layer 270 may serve as a storage node where charges transferred from the write transistor 210 may be stored. For example, the second gate insulation layer 270 may include a silicon oxide, a silicon nitride, a silicon oxynitride, an aluminum oxide, a hafnium oxide, a zirconium oxide, or two or more combinations thereof.

The second source 280 may be located on one side of the horizontal channel layer 275. The second drain 285 may be located on the other side of the horizontal channel layer 275. In some embodiments, a second conductive type impurity, such as a high concentration n-type impurity, may be implanted into the semiconductor material layer for the horizontal channel layer 275 exposed by the second gate 270 to form the second source 280 and the second drain 285.

The read word line 290 may be connected to a sidewall of the second source 280. The read bit line 295 may be connected to a sidewall of the second drain 285.

In FIG. 6B, reference numeral 300 indicates a peripheral circuit layer. For example, the peripheral circuit layer 300 may be disposed below the write bit line 245, but the embodiments may not be limited in this way. Further, the peripheral circuit layer 300 may generate various control signals and various input and output voltages to be provided to the memory cells. The peripheral circuitry layer 300 may be integrated on a separate wafer, and then wafer bonded to the wafer on which the memory cells are integrated

Further, while the embodiments illustrate a read transistor stacked over the write transistor, it may be possible to stack a vertically channeled write transistor on the horizontally channeled read transistor, without limitation.

As described in the embodiments, the one-way switch may be formed between the write transistor and the read transistor. The one-way switch may prevent data stored in the read transistor from flowing toward the write bit line connected with the write transistor when it is in an unselected state. Accordingly, the data retention rate of the capacitorless memory cell may be improved.

Furthermore, the one-way switch may be configured in the form of the wiring including the n-type semiconductor layer and the metal layer or the n-type semiconductor layer and the p-type semiconductor layer, so that data loss of the memory cell may be prevented by a simple structure and manufacturing method.

While the present invention has been described in detail with reference to specific embodiments, the invention is not limited to the above embodiments and may be implemented with many modifications by one having ordinary skill in the art without departing from the scope and the technical concepts of the present disclosure. Furthermore, the embodiments may be combined to form additional embodiments.

What is claimed is:

1. A semiconductor memory device comprising:
a write transistor configured to output a signal of a write bit line as data in response to a signal of a write word line;
a read transistor configured to store the data and to output the stored data to a read bit line in response to a signal of a read word line; and
a one-way switch configured to transmit the data in one direction from the write transistor to the read transistor.

2. The semiconductor memory device of claim 1, wherein the one-way switch comprises a diode, and the diode comprises an anode in connection with the write transistor and a cathode in connection with the read transistor.

3. The semiconductor memory device of claim 2, wherein the one-way switch comprises a Schottky barrier diode or a PN diode.

4. The semiconductor memory device of claim 1,
wherein the one-way switch comprises a diode with an anode and a cathode,
wherein the write transistor comprises a first gate, a first source and a first drain, the first gate is connected to the write word line, the first source is connected to the write bit line, and the first drain is connected to the anode, and
wherein the read transistor comprises a second gate, a second source and a second drain, the second gate is connected to the cathode, the second source is connected to the read word line, and the second drain is connected to the read bit line.

5. The semiconductor memory device of claim 1,
wherein each of the write transistor and the read transistor is arranged in two dimensions and comprises a horizontal channel,
wherein the one-way switch comprises a wiring structure connected between a drain of the write transistor and a gate of the read transistor, and
wherein the wiring structure comprises one of a Schottky barrier diode structure including a drain electrode in contact with a drain of the write transistor and an n-type semiconductor layer in contact with the drain electrode; and a p-n junction diode structure including a p-type semiconductor layer in contact with a drain of the write transistor and an n-type semiconductor layer in contact with the p-type semiconductor layer and in contact with a gate of the read transistor.

6. The semiconductor memory device of claim 1,
wherein the write transistor and the read transistor are three-dimensionally stacked, and
wherein each of the write transistors has a vertical channel, and each of the read transistors has a horizontal channel.

7. The semiconductor memory device of claim 1,
wherein the write word line and the read word line extend parallel along a first direction, and
wherein the write bit line and the read bit line extend parallel along a second direction perpendicular to the first direction.

8. A semiconductor memory device comprising:
a write bit line;
a write transistor electrically connected to the write bit line and stacked over the write bit line;
a one-way switch stacked over the write transistor; and
a read transistor stacked over the unidirectional switch.

9. The semiconductor memory device of claim 8, wherein the write transistor comprises:
a first channel pillar including a semiconductor material and extending in a direction perpendicular to a surface of the write bit line;
a first gate insulation layer formed to surround an outer circumferential surface of the first channel pillar;
a first gate formed to surround an outer circumferential surface of the first gate insulator and electrically connected to the write word line;
a first source formed in a lower region of the first channel pillar and electrically coupled to the write bit line; and
a first drain formed in an upper region of the first channel pillar and electrically connected to the one-way switch.

10. The semiconductor memory device of claim 9, wherein a first source contact electrode including a metal is formed between the first source and the write bit line.

11. The semiconductor memory device of claim 8, wherein the one-way switch comprises:
a first drain contact electrode formed on the first drain, and including a metal; and
an n-type semiconductor layer formed on the first drain contact electrode.

12. The semiconductor memory device of claim 8, wherein the one-way switch comprises:
a p-type semiconductor layer formed on the first drain and electrically connected to the first drain; and
an n-type semiconductor layer formed on the p-type semiconductor layer to be positioned adjacent to the p-type semiconductor layer.

13. The semiconductor memory device of claim 12, wherein the one-way switch further comprises a first drain contact electrode between the first drain and the p-type semiconductor layer.

14. The semiconductor memory device of claim 8, wherein the read transistor comprises:
a second gate electrically connected to the one-way switch and stacked over the one-way switch;
a second gate insulation layer formed on the second gate;
a second channel layer formed on the second gate insulation layer;
a second source located on one side of the second channel layer and electrically coupled to the read word line; and
a second drain located on the other side of the second channel layer and electrically connected to the read bit line.

15. The semiconductor memory device of claim 8, further comprising a peripheral circuit positioned below the write bit line to provide at least one control signal and at least one drive voltage to the write bit line, the write transistor and the read transistor.

16. A semiconductor memory device comprising:
a write transistor including a first source in connection with a write bit line, a vertical channel layer formed on the first source, and a first drain formed on the vertical channel, a first gate insulation layer configured to surround outer circumferential surfaces of the first source, the vertical channel layer and the first drain, and a first gate configured to surround an outer circumferential surface of the first gate insulation layer;
a forward diode stacked over the first drain of the write transistor; and
a read transistor including a second gate stacked over the forward diode, a second gate insulation layer formed on the second gate, a horizontal channel layer positioned on the second gate insulation layer, a second source positioned on one side of the horizontal channel layer, and a second drain positioned on the other side of the horizontal channel layer.

17. The semiconductor memory device of claim 16, further comprising:
a read word line in contact with one side of the second source; and
a read bit line in contact with the other side of the second drain.

18. The semiconductor memory device of claim 16, wherein the forward diode comprises:
a first drain contact electrode including a metal in contact with the first drain; and
an n-type semiconductor layer formed on the first drain contact electrode.

19. The semiconductor memory device of claim 16, wherein the forward diode comprises:
a p-type semiconductor layer formed on the first drain in electrical communication with the first drain; and
an n-type semiconductor layer formed on the p-type semiconductor layer positioned adjacent to the p-type semiconductor layer.

20. A semiconductor memory device comprising:
a write bit line;
a write transistor electrically connected to the write bit line;
a read transistor electrically connected to a read word line and a read bit line; and
a one-way switch operatively connected between a first drain of the write transistor and a gate of the read transistor,
wherein the write transistor comprises a first channel, a first source electrically coupled to the write bit line, and the first drain.
